(19) United States
(12) Patent Application Publication
(10) Pub. No.: US 2021/0193248 A1
(43) Pub. Date: Jun. 24, 2021

(54) NEAR MISS-BASED REFRESH FOR READ DISTURB MITIGATION

(71) Applicant: Intel Corporation, Santa Clara, CA (US)

(72) Inventors: Lunkai ZHANG, Portland, OR (US); Rakan MADDAH, Portland, OR (US); Prashant S. DAMLE, Portland, OR (US)

(21) Appl. No.: 17/132,902

(22) Filed: Dec. 23, 2020

(51) Int. Cl. G11C 29/42; G11C 29/44; G11C 29/12; G11C 29/18; G11C 29/00

(52) U.S. Cl. CPC G11C 29/42; G11C 29/44; G11C 29/783; G11C 29/18; G11C 29/1201

(57) ABSTRACT

A “near miss” based refresh scheme performs refreshes to read disturbed codewords proactively (or on-demand). In one example, a controller receives a read request to a target address (e.g., from a host memory controller). The read request is sent to memory, and the memory returns the read data. ECC logic decodes the read data and determines the number of error bits in the read data. If the number of error bits is greater than a threshold, a refresh write command is sent to the command queue. If an outstanding write command to the same address is already in the queue, the refresh write can be dropped and the outstanding write command converted into a refresh write command. A data cache can service read commands to the target address until the near miss-based refresh command completes.

### FIELD

The descriptions are generally related to memory, and more particularly, techniques for mitigating read disturbs in memory.

### BACKGROUND

Memory resources have innumerable applications in electronic devices and other computing environments. Demand for smaller, faster, lower power, and higher density memory has led to the development of new memory technologies. During the development of new memory technologies, a variety of challenges may be encountered such as challenges related to the manufacturing process, infrastructure, and reliability. For example, one challenge that may be encountered is the prevention or mitigation of read disturb in memory.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing at least one implementation of the invention that includes one or more particular features, structures, or characteristics. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a block diagram of a system that includes a non-volatile memory device that includes logic for performing near miss-based refreshes.

FIG. 2 illustrates an example of memory control logic for performing near miss-based refreshes.

FIG. 3 is a flow diagram of an example of a method of refresh for read disturb mitigation.

FIG. 4 illustrates an example of memory control logic for performing near miss-based refreshes with a near miss data cache.

FIGS. 5A and 5B are flow diagrams of examples of methods of refresh for read disturb mitigation using a data cache.

FIG. 6 shows a graph of the number of bit errors versus the number of reads with and without near miss-based refreshes.

FIG. 7 is an example of a cross-point memory cell.

FIG. 8 illustrates an example of a portion of a memory cell array.

FIG. 9 provides an exemplary depiction of a computing system in which a near miss based refresh scheme may be implemented.

Descriptions of certain details and implementations follow, including a description of the figures, which may depict some or all of the embodiments described below, as well as discussing other potential embodiments or implementations of the inventive concepts presented herein.

### DETAILED DESCRIPTION

A near miss-based refresh scheme pro-actively refreshes addresses at risk of data failure due to read disturb, which can significantly reduce the probability of uncorrectable errors in memory.

Crosspoint memory can be susceptible to read disturb, in which the stored state in a cell changes when read frequently, leading to data errors. Read disturb in crosspoint memory may involve disturbing the cell being actively read without affecting neighboring cells. Thus, read disturb in a target cell is different than read disturb that affects neighboring cells. In memory susceptible to read disturb in a target cells, cumulative reads to a target cell may increase the probability of read disturb in the target cell.

Existing techniques for preventing or mitigating read disturb include statistical refreshes and periodic data scrub refreshes (sequential refresh). A refresh operation can recover a disturbed cell by reading the cell and then writing the data back. Statistical refresh involves issuing a refresh write operation every x number of total media reads. Statistical refresh may be based on a global read counter shared by codewords. While statistical refreshes may work for most codewords in memory, a statistical technique may be insufficient for some codewords (e.g., the statistical “tail” codewords).

Periodic data scrub refreshes involve performing a periodic refresh write operation to every codeword in memory. However, some a periodic data scrub scheme refreshes codewords sequentially, and may nor refresh some codewords soon enough to prevent data loss. Accordingly, existing techniques for preventing read disturb are insufficient for preventing data loss in some cases where codewords accumulate enough reads to cause bit failures beyond the ECC capability before being refreshed.

In contrast, a “near miss” based refresh scheme performs refreshes to read disturbed codewords proactively (or on-demand) rather than statistically. In one example, a memory-side controller receives a read request to a target address (e.g., from a host memory controller). The read request is sent to memory, and the memory returns the read data. ECC logic decodes the read data and determines the number of error bits in the read data. If the number of error bits is greater than a threshold, a refresh write command is sent to the command queue. If an outstanding write command to the same address is already in the queue, the refresh write can be dropped and the outstanding write command converted into a refresh write command.

Thus, issuing refresh writes based on the state on the address being read (e.g., when the number of bit errors accumulates above the trigger threshold) prevents the data at the target address from becoming uncorrectable. Consequently, the probability of uncorrectable errors due to read disturb is significantly reduced making the memory/storage products more reliable and with improved performance. Furthermore, checking the queue for other writes to the same target address after issuing a refresh eliminates redundant writes due to the on-demand refresh scheme, further improving system performance.

Additionally, the refresh logic can include a cache to store read data until a refresh operation has completed. When an address triggers a near miss-based refresh (e.g., when the number of error bits is greater than a threshold), it may be possible for the memory to be exposed to additional reads to the same address before the refresh write completes. Such additional reads could increase the probability of data loss before the refresh operation is performed. Thus, to prevent additional reads to a codeword that is undergoing a refresh, a data cache can service subsequent read requests until the address is refreshed.

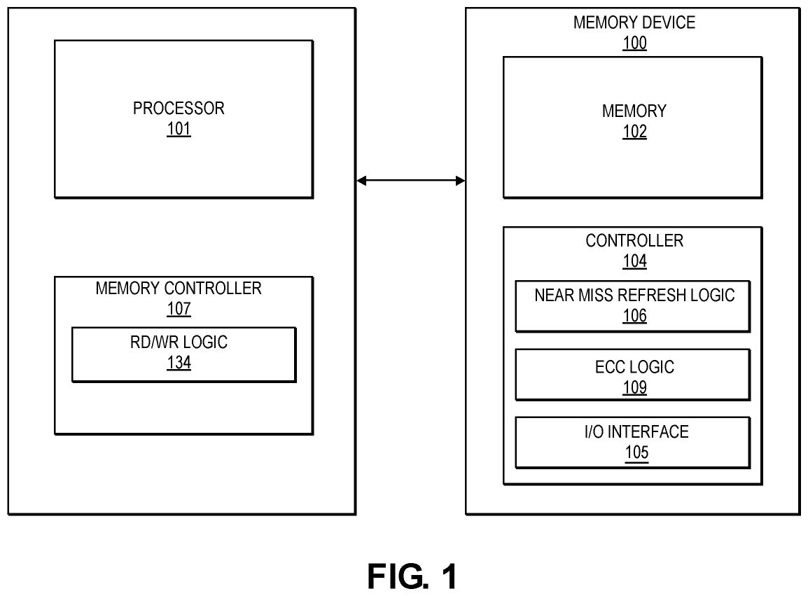

FIG. 1 is a block diagram of a system that includes a non-volatile memory device that includes logic for performing near miss-based refreshes.

The system of FIG. 1 includes components of a memory subsystem having memory 102 to store and provide data in response to operations of processor 101. The system receives memory access requests from the processor 101, which is processing logic that executes operations based on data stored in memory 102 or generates data to store in memory 102. The processor 101 can be or include a host processor, central processing unit (CPU), microcontroller or microprocessor, graphics processor, peripheral processor, application specific processor, artificial intelligence (AI) or machine learning processor, an accelerator, or other processor, and can be single core or multicore.

The system includes a memory controller (e.g., host memory controller) 107, which represents logic to interface with the memory device 100 and manage access to data stored in the memory 102. In one example, the memory controller 107 is integrated into the hardware of the processor 101. In one example, the memory controller 107 is standalone hardware, separate from the processor 101. The memory controller 107 can be a separate circuit on a substrate that includes the processor. The memory controller 107 can be a separate die or chip integrated on a common substrate with a processor die (e.g., as a system on a chip (SoC)). In one example, the memory controller 107 is an integrated memory controller (iMC) integrated as a circuit on the processor die. In one example, the memory 102 can be included on an SoC with the memory controller 107 and/or the processor 101.

In the illustrated example, the memory controller 107 includes read/write logic 134, which includes hardware to interface with the memory device 100. The logic 134 enables the memory controller 107 to generate read and write commands to service requests for data access generated by the execution of instructions by processor 101.

The memory 102 represents memory resources for the system. The memory 102 includes one or more memory arrays of memory cells. The memory 102 may include volatile and/or nonvolatile memory. In one example, the memory 102 includes one or more of a crosspoint memory array, a phase change memory, a chalcogenide-based memory, or a persistent memory. The memory device 100 includes a controller 104, which typically includes control circuitry to control the memory device's internal operations to execute commands received from memory controller 107. The controller 104 can be, for example, on a same module (e.g., dual inline memory module (DIMM)), same package, and/or same die as the memory 102. In one example, the controller 104 is an application specific integrated circuit (ASIC) or other hardware circuitry. The controller 104 can control any of timing, voltage levels, addressing, I/O (input/output) margining, scheduling, and error correction for memory 102. Thus, the controller 104 includes I/O interface circuitry 105 to handle receipt and transmission of commands and data from the memory controller 107, and to control the access to the memory array. The I/O interface circuitry for controlling access to the memory array can include decode logic, including logic to address specific rows or columns, bit lines or word lines, or otherwise address specific bits of data.

The controller 104 includes ECC logic 109 to perform error detection and correction on data. In one example, the ECC logic 109 includes circuitry configured to decode codewords read from the memory 102, determine whether data read from the memory 102 contains errors, and correct errors. In one example, the ECC logic 109 also includes encoding logic to encode write data before it is sent to the memory 102. The ECC logic 109 encodes and/or decodes according to an ECC algorithm such as Reed-Solomon codes, Bose-Chaudhuri-Hocquenghem (BCH) codes, or other ECC algorithm.

The controller 104 also includes near miss refresh logic 106. The refresh logic 106 includes circuitry to detect when the number of bit errors exceeds a threshold and issue a refresh to that target address.

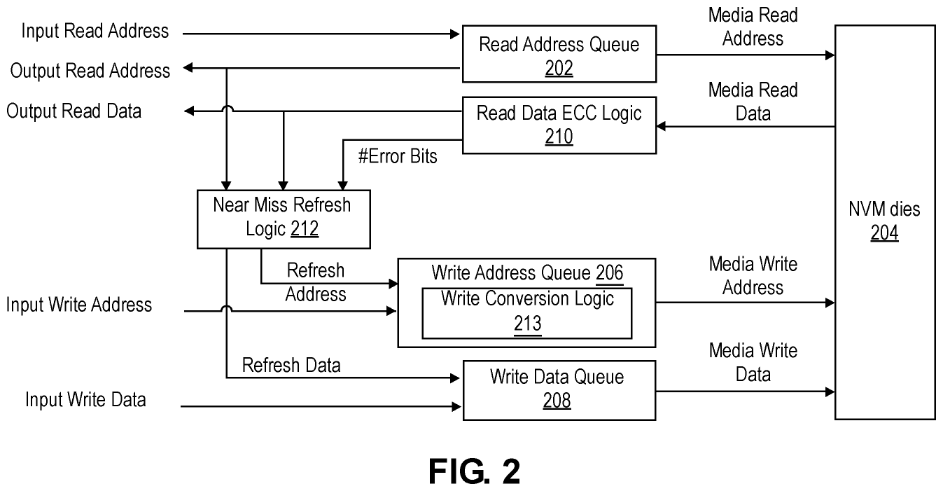

FIG. 2 illustrates an example of memory control logic for performing near miss-based refreshes. The logic of FIG. 2 can be included in a memory controller such as, for example, the controller 104 of FIG. 1. The example of FIG. 2 includes a read address queue 202 to receive read addresses for incoming read commands. The read addresses are then sent from the read address queue 202 to the non-volatile memory (NVM dies) 204. The non-volatile memory 204 can be the same as, or similar to, the memory 102 of FIG. 1 described above. Similarly for write commands, the logic of FIG. 2 includes a write address queue 206 to receive write addresses for incoming write commands and a write data queue 208 to receive write data for incoming write commands. The write address and write data are sent from the write address queue 206 and write data queue 208, respectively, to the non-volatile memory 204.

The logic of FIG. 2 also includes a ECC logic 210 to detect and correct bit errors in the read data from the non-volatile memory 204. As mentioned above, memory is protected by an error correction code (ECC). For example, write data is encoded with an ECC, which produces a codeword that includes one or more redundant bits (e.g., ECC bits) according to an ECC algorithm. Therefore, read data received from the non-volatile memory includes one or more codewords that is then decoded by the ECC logic 210. Decoding the read data provides the number of bits that are in error. If the number of bit errors is lower than the maximum number of bits that can be corrected with the ECC, the ECC logic 210 corrects the bit errors. The read data is then sent to the requester.

The ECC logic 210 also sends a signal indicating the number of bits in error for the last read address to near miss refresh logic 212. The near miss refresh logic 212 compares the number of bit errors for the read address to a threshold (e.g., with comparator circuitry). The threshold value may be a programmable (e.g., by the BIOS (basic input output system) and/or by firmware during runtime) or fixed value. In one example, the threshold value provides enough guard band from the ECC fail point and a trigger rate without penalizing performance. In one example, the threshold value is half or less than the maximum number of bit errors that can be corrected in a codeword by the ECC logic 210. In other examples, the threshold value may be greater than half the maximum number of correctable bit errors. The optimal threshold value will vary depending on the memory characteristics, among other things such as the typical memory access patterns. In some examples, setting the threshold value at half or less than the maximum number of correctable bit errors may provide better read disturb prevention coverage than a threshold value that is greater than half the maximum correctable bit errors.

If the number of bit errors is high, it may be an indication that the address has undergone stress due to reads and is in a read disturbed state (although a high number of bit errors may also have other causes). If the refresh logic determines that the number of bit errors is greater than the threshold, the refresh logic 212 causes a refresh write command for the target address to be sent to the command queue. For ease of reference, a refresh operation at a target address based on the bit errors at that target address exceeding a threshold is referred to as a “near miss-based refresh.” For example, the refresh logic 212 sends the refresh address to the write address queue 206 and the refresh data to the write data queue 208. The refresh address is the address of the read command with the high number of bit errors that triggered the refresh. The refresh data is the read data received from the ECC logic for the read command address.

After the refresh command address is sent to the write address queue 206, logic 213 checks if there are other write commands in the queue to the same address. Write commands can include regular write commands, partial write commands, force write commands, refresh commands, or any other type of command that causes data to be written to the memory 204. In response to a determination that there are other write commands to the same address, the refresh command triggered by the high number of bit errors can be dropped. If the other write command is a write command that does not write to all bits in the codeword, the other write command can be converted into a refresh command to cause all bits in the codeword to be written. If the other write command is a command type to write all bits to the code word (e.g., a refresh command or a force write command), the other command does not need to be converted into a refresh. The refresh command address and data are then sent to the memory 204 to perform the refresh of the address before read disturb results in an uncorrectable failure.

Thus, the near miss refresh logic examines the number of ECC corrected bits of current read. If it surpasses the pre-programed near miss threshold, the logic 212 will issue the near miss-based refresh request through the write path.

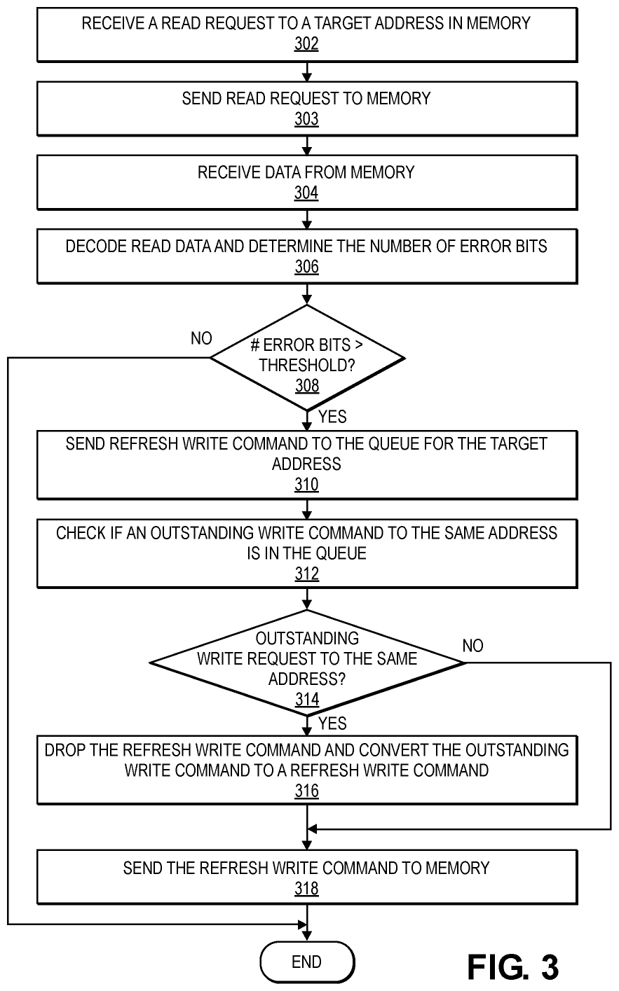

FIG. 3 is a flow diagram of an example of a method of refresh for read disturb mitigation. The method of FIG. 3 can be performed by hardware logic (e.g., circuitry) in a memory controller. For example, the controller 104 of FIG. 1 or the control logic of FIG. 2.

The method of FIG. 3 starts with receiving a read request to a target address in memory, at 302. For example, referring to FIG. 1, a host memory controller 107 sends a read request or read command to the memory device 100. The controller 104 receives the read request (e.g., via I/O interface circuitry 105). Referring to FIG. 2, receiving a read request involves receiving a read address (via an I/O interface) to a read address queue 202.

Referring again to the method of FIG. 3, after receiving the read request, the read request is sent to memory, at 303. For example, referring to FIG. 2, the read address queue 202 sends the read address to the memory 204. Referring again to the method of FIG. 3, after sending the read request to memory, the control logic receives read data from the memory in response to the read request, at 304. For example, referring to FIG. 2, the ECC logic 210 receives the read data from the memory 204.

After receipt of the data from memory, the ECC logic can decode read data and determine the number of error bits in the read data, at 306. For example, referring to FIG. 2, the ECC logic 210 decodes the codeword received from memory 204 and detects and corrects bit errors. The number of error bits can then be sent to refresh logic 212. Referring again to the method of FIG. 3, if the number of errors bits is not greater than a threshold, 308 NO branch, the method ends. If the number of error bits is greater than the threshold, 308 YES branch, a refresh write command for the target address is sent to the command queue. For example, referring to FIG. 2, the refresh logic 212 sends the refresh address to the write address queue 206 and the refresh data to the write data queue 208.

After sending the refresh write command triggered by the high bit errors, logic checks if an outstanding write command to the same address is present in the queue, at 312. For example, referring to FIG. 2, the logic 213 compares addresses of write commands in the queue with the target address of the refresh write command. If there is not already a write command to the target address in the queue, the refresh write command can be sent to the memory, at 318. If there is another write command in the queue to the same target address, then the refresh write command triggered by the high bit errors is redundant and can be dropped, at 316. The existing write command to the target address can be converted to a refresh write command to write all the bits in the codeword, at 316. In one example, converting a command from one type of command to another involves modifying the op-code of the command. For example, modifying a write command's op-code to a refresh write op-code. The refresh write command (e.g., the write command converted to a refresh write command) can then be sent to the memory, at 318.

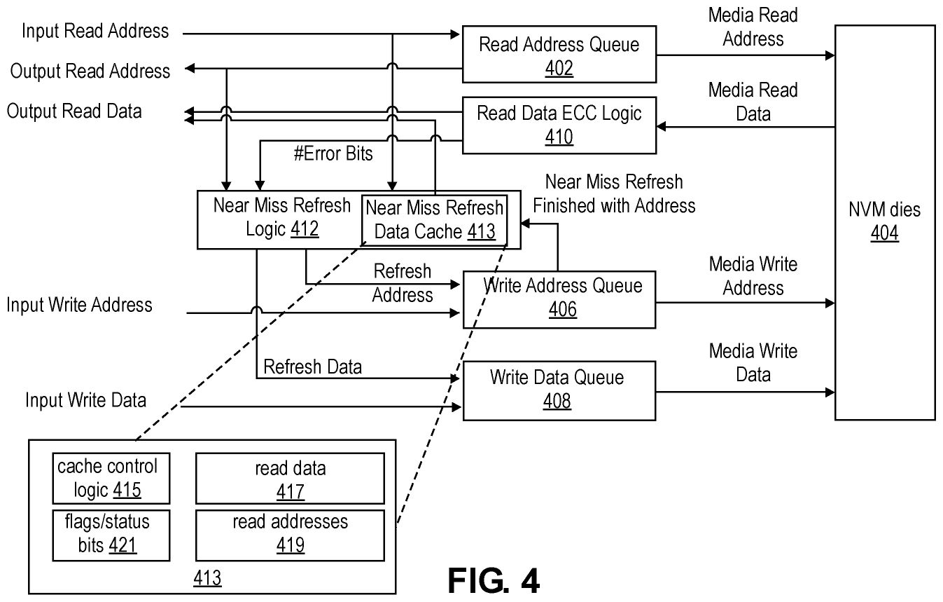

A near miss-based refresh scheme to mitigate read disturb can also include a data cache to service subsequent read requests to an address that has an outstanding refresh. FIG. 4 illustrates an example of memory control logic for performing near miss-based refreshes with a near miss data cache. The logic of FIG. 4 can be included in a memory controller such as, for example, the controller 104 of FIG. 1. FIG. 4 includes some of the same features as the logic of FIG. 2. For example, FIG. 4 includes a read address queue 402, a non-volatile memory 404, a write address queue 406, a write data queue 408, ECC logic 410, and near miss refresh logic 412, which can be the same as, or similar to, the features of FIG. 2 discussed above.

Thus, the near miss refresh logic 412 receives a signal indicating the number of bit errors that were detected in a codeword and compares the number of bit errors for the read address to a threshold. If the refresh logic 412 determines that the number of bit errors is greater than the threshold, the refresh logic 412 causes a refresh write command to be sent to the command queue. For example, the refresh logic 412 sends the refresh address to the write address queue 406 and the refresh data to the write data queue 408. The refresh write is then sent to the memory 404 to refresh the data stored at the target address.

After the refresh logic 412 sends a refresh write command to the queue for subsequent transmission to the memory, additional read commands to the same target address may be received. Such additional reads may increase the probability of data loss before the refresh write command completes. For example, some memory subsystems prioritize read requests over write commands. In such a system, read requests to an address may be sent to the memory before a refresh write, even if the refresh write entered the command queue before the read requests. To prevent additional reads to a codeword that is undergoing a refresh triggered due to the bit errors exceeding a threshold, a data cache can service subsequent read requests until the address is refreshed. In the example of FIG. 4, the refresh logic 412 is augmented with a data cache 413. The data cache includes memory or storage to store addresses 419 and corresponding data 417, as well as flags or status bits 421 for the entries of the cache 413. The data cache 413 also includes cache control logic 415 to operate the cache.

The data cache 413 receives incoming read addresses and checks if the read address is stored in the cache. For example, cache control logic 415 checks input read addresses against addresses 419 and outputs a signal to indicate whether there was a cache hit or not. If the address is stored in the cache (e.g., if there is a cache hit), the read data is retrieved from the cache and the read request can be dropped from the queue. For example, the cache control logic 415 can sent a signal to the read address queue 402 to cause the read request to be dropped or invalidated so that it is not sent to the memory 404. Thus, additional writes to the read disturbed address can be prevented until the refresh request completes. Once the near miss-based refresh operation completes (as indicated by a signal from the write address queue 406 to the refresh logic 412), the entry of the cache 413 for the target address can be invalidated so that subsequent read requests are serviced from the memory 404. Note that although FIG. 4 does not show write conversion logic such as logic 213 of FIG. 2, a refresh scheme can include one or both the conversion logic 213 of FIG. 2 and the data cache 413 of FIG. 4.

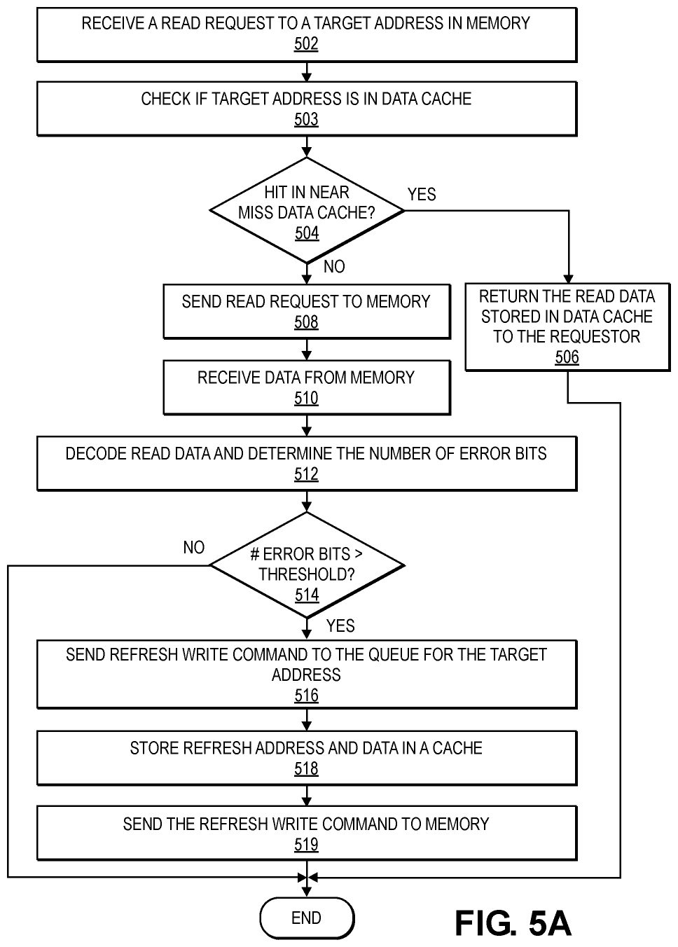

FIGS. 5A and 5B are flow diagrams of examples of methods of refresh for read disturb mitigation using a data cache. The method of FIG. 5 can be performed by hardware logic (e.g., circuitry) in a memory controller. For example, the controller 104 of FIG. 1 or the control logic of FIG. 2.

FIG. 5A begins with receiving a read request to a target address in memory, at 502. For example, referring to FIG. 4, receiving a read request involves receiving a read address (via an I/O interface) to a read address queue 402. The read address is also received by the data cache 413. Referring again to the method of FIG. 5A, the cache is checked for the target address of the read request, at 503. For example, referring to FIG. 4, cache control logic 415 of the cache 413 checks if the target address is stored in the data cache. If the target address is not stored in memory, 504 NO branch, it indicates that there is not an outstanding near miss-based refresh operation to the target address. The read request can then be sent to memory, at 508. The data is received rom memory, at 510. ECC logic decodes the read data and determines the number of error bits, at 512. If the number of error bits are not greater than a threshold value, 514 NO branch, the method ends. If the number of error bits is greater than a threshold value, 514 YES branch, a refresh write command for the target address is sent to the queue, at 516.

Once the refresh write to the target address is triggered, the target address for the refresh command and the refresh data are stored in a cache, at 518. For example, referring to FIG. 4, the refresh logic 412 causes the refresh address and refresh data to be stored in the cache 413 in addition to causing the refresh write command to the target address to be sent to the queues 406 and 408. The refresh write command is sent to memory, at 519. Until the refresh write command completes, subsequent read requests to the target address can be serviced by the cache instead of being sent to memory. For example, if a received address returns a hit in the cache, 504 YES branch, the cache returns the read data stored for that address to the requester, at 506.

FIG. 5B is performed by cache control logic of a cache (e.g., of the cache control logic 415 of FIG. 4). The cache control logic receives a signal indicating that the near miss-based refresh to the target address has completed, at 542. For example, referring to FIG. 4, the write address queue 406 sends a near miss-based refresh completion signal to the near miss refresh logic 412 and/or to the cache control logic 415 for a particular address. The cache control logic then looks up the corresponding entry in the cache, at 544. The cache control logic invalidates the data entry of the cache, at 546. For example, referring to FIG. 4, the cache control logic 415 updates the status bits for the entry to indicate the entry is invalid. After the entry is invalidated, the entry is available for the next addresses targeted by a near miss-based refresh.

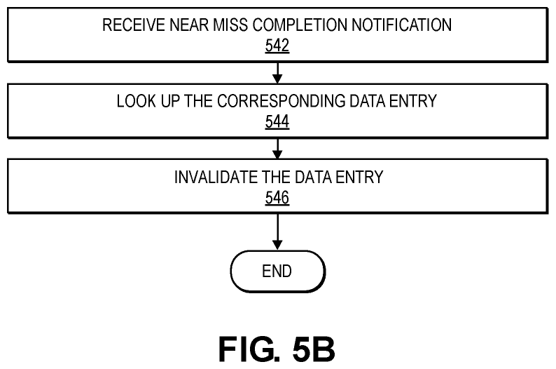

FIG. 6 shows a graph of the number of bit errors versus the number of reads with and without near miss-based refreshes. The plot 601 shows an example of how, in some memory technologies, the number of bit errors at an address can increase as a function of the number of reads to the address. In the illustrated example, the rate of bit error increase is relatively slow and steady and closely correlated to the number of writes. However, if not addressed (e.g., with a refresh operation), the number of bit errors can increase until the maximum ECC capability is exceeded. In contrast, the plot 603 shows an example of how near miss-based refreshes can prevent the number of bit errors from approaching or exceeding the maximum ECC capability of the memory system. Once the number of bit errors for a particular address reaches or exceeds the threshold, a near miss-based refresh is issued to that address (triggered at points 602).

Thus, a near miss-based refresh scheme performs refreshes to read disturbed codewords proactively (or on-demand). A near miss-based refresh scheme uses the number of bit errors corrected by the ECC engine on a read operation as an indicator of the health of the codeword to decide whether to issue a refresh operation. A near miss-based refresh scheme can be implemented instead of or in addition to statistical or periodic refresh schemes to prevent data loss due to read disturb in target cells.

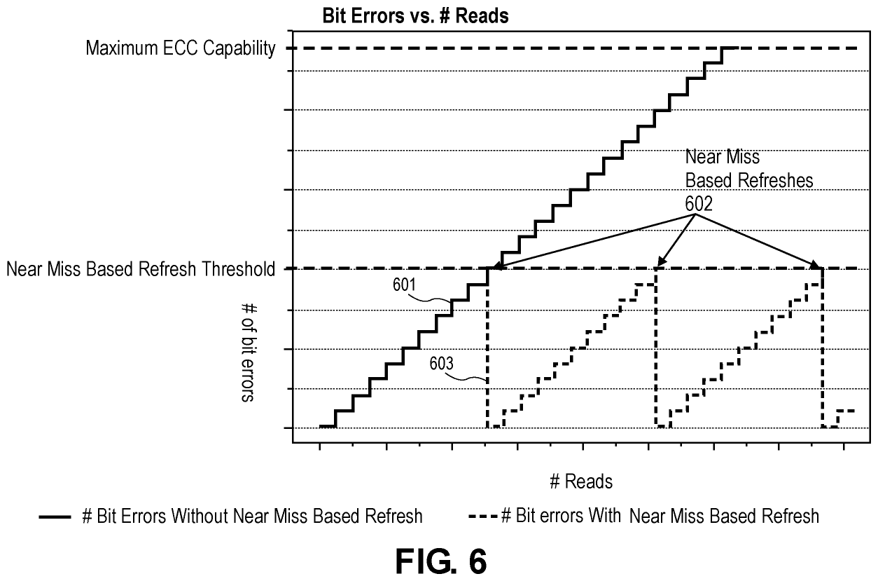

The techniques and circuitry discussed herein can apply to various memory technologies. A crosspoint memory device is one example in which a near miss-based refresh scheme may be implemented. FIG. 7 illustrates an example of a cross-point memory cell. FIG. 7 illustrates a memory cell 700. The memory cell 700 includes one or more layers of material 702 to store data and aid in selection of the memory cell 700. For example, the memory cell 700 can include a storage material 702 (e.g., to form a memory element), a selector material (e.g., to form the switch element), or both, between access lines 704 and 706. In one example, the memory cell includes a layer of storage material and a separate layer of selector material. In one example, both the selector and the storage element have tunable threshold voltages. In one example, the memory cell 700 includes a self-selecting material that exhibits both memory and selection effects. A self-selecting material is a storage material that enables selection of a memory cell in an array without requiring a separate layer of material for selection of the cell. In one example, a self-selecting memory cell includes a single layer of material that acts as both a selector element to select the memory cell and a memory element to store a logic state. A material exhibits memory effects if the material can be put in one of multiple (e.g., 2 or more) stable states (e.g., via a write operation), and subsequently read back (e.g., via a read operation). In one example, the switch element formed from the select material is an ovonic switch. The techniques described herein are not dependent on or specific to a particular storage material. However, some non-limiting examples of storage material follow.

In some examples, the storage material is a phase change material. In other examples, the storage material can be in one or multiple stable states without a change in phase. In one example, the memory element, switching element, or both are amorphous semiconductor threshold switches (e.g., ovonic threshold switches) using an amorphous material such as an amorphous chalcogenide material or other amorphous material. An ovonic threshold switch remains in an amorphous state which distinguishes it from an ovonic memory, which generally changes between amorphous and crystalline states. In one example, an ovonic memory is used in series with an ovonic threshold switch. In such case, the ovonic threshold switch operates as the switch element for the ovonic memory. Whether the memory material of the memory cell changes phase or not, in one example, the memory could be referred to as a resistance-based memory. In a resistance-based memory, the bit stored by a memory cell is based on the resistive state of the memory cell.

Examples of storage material can include one or more of: tellurium (Te), selenium (Se), germanium (Ge), antimony (Sb), bismuth (Bi), lead (Pb), tin (Sn), indium (In), silver (Ag), arsenic (As), sulfur (S), phosphorus (P), molybdenum (Mo), gallium (Ga), aluminum (Al), oxygen (O), nitrogen (N), chromium (Cr), gold (Au), niobium (Nb), palladium (Pd), cobalt (Co), vanadium (V), nickel (Ni), platinum (Pt), titanium (Ti), tungsten (W), tantalum (Ta) or other materials. For example, the storage material may include one or more chalcogenide materials such as such as Te—Se, Ge—Te, In—Se, Sb—Te, Ge—Sb, Ta—Sb—Te, Ga—Sb, In—Sb, As—Te, As—Se, Al—Te, As—Se—Te, Ge—Sb—Te, Ge—As—Se, Te—Ge—As, V—Sb—Se, Nb—Sb—Se, In—Sb—Te, In—Se—Te, Te—Sn—Se, V—Sb—Te, Se—Te—Sn, Ge—Se—Ga, Mo—Sb—Se, Cr—Sb—Se, Ta—Sb—Se, Bi—Se—Sb, Mo—Sb—Te, Ge—Bi—Te, W—Sb—Se, Ga—Se—Te, Ge—Te—Se, Cr—Sb—Te, Sn—Sb—Te, W—Sb—Te, Sn—Sb—Bi, In—Sb—Ge, As—Sb—Te, Ge—Te—Ti, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Se—Te—In, As—Ge—Sb—Te, Se—As—Ge—In, Ge—Sb—Se—Te, Ge—Sn—Sb—Te, Ge—Te—Sn—Ni, Ge—Te—Sn—Pd, and Ge—Te—Sn—Pt, Si—Ge—As—Se, In—Sn—Sb—Te, Ge—Se—Te—Si, Si—Te—As—Ge, Ag—In—Sb—Te, Ge—Se—Te—In—Si, Se—As—Ge—Si—In, or other materials capable of being programmed to one of multiple states. One or more elements in a chalcogenide material may be dopants. For example, the storage material may include dopants such as: aluminum (Al), oxygen (O), nitrogen (N), silicon (Si), carbon (C), boron (B), zirconium (Zr), hafnium (Hf), or a combination thereof. The storage material may include other materials or dopants not explicitly listed.

As mentioned above, some memory cells include a separate layer of selector material to form a switch element. The selector material may include a chalcogenide material (e.g., a chalcogenide glass) or other material capable of operating as a selection element. In one example, the selector material includes one or more of: silicon (Si), germanium (Ge), selenium (Se), arsenic, tellurium (Te), or other materials. In one example, the selector material includes Si—Ge—As—Se, As—Ge—Te—Si, or other selector material. The selector material may also include dopants such as: aluminum (Al), oxygen (O), nitrogen (N), silicon (Si), carbon (C), boron (B), zirconium (Zr), hafnium (Hf), or a combination thereof. The selector material may include other materials or dopants not explicitly listed.

The access lines 704, 706 electrically couple the memory cell 700 with circuitry that provides power to and enables access to the memory cell 700. The term “coupled” can refer to elements that are physically, electrically, and/or communicatively connected either directly or indirectly, and may be used interchangeably with the term “connected” herein. Physical coupling can include direct contact. Electrical coupling includes an interface or interconnection that allows electrical flow and/or signaling between components. Communicative coupling includes connections, including wired and wireless connections, that enable components to exchange data. The access lines 704, 706 can be referred to as a bit line and word line, respectively. The word line is for accessing a particular word in a memory array and the bit line is for accessing a particular bit in the word. The access lines 704, 706 can be composed of one or more metals including: Al, Cu, Ni, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; conductive metal silicide nitrides including TiSiN and WSiN; conductive metal carbide nitrides including TiCN and WCN, or any other suitable electrically conductive material.

In one example, electrodes 708 are disposed between storage material 702 and access lines 704, 706. Electrodes 708 electrically couple access lines 704, 706 with storage material 702. A memory cell with separate layers of storage and selector material may also include an electrode between the layers of storage and selector material. Electrodes 708 can be composed of one or more conductive and/or semiconductive materials such as, for example: carbon (C), carbon nitride (CₓN_{y}); n-doped polysilicon and p-doped polysilicon; metals including, Al, Cu, Ni, Cr, Co, Ru, Rh, Pd, Ag, Pt, Au, Ir, Ta, and W; conductive metal nitrides including TiN, TaN, WN, and TaCN; conductive metal silicides including tantalum silicides, tungsten silicides, nickel silicides, cobalt silicides and titanium silicides; conductive metal silicides nitrides including TiSiN and WSiN; conductive metal carbide nitrides including TiCN and WCN; conductive metal oxides including RuO₂, or other suitable conductive materials.

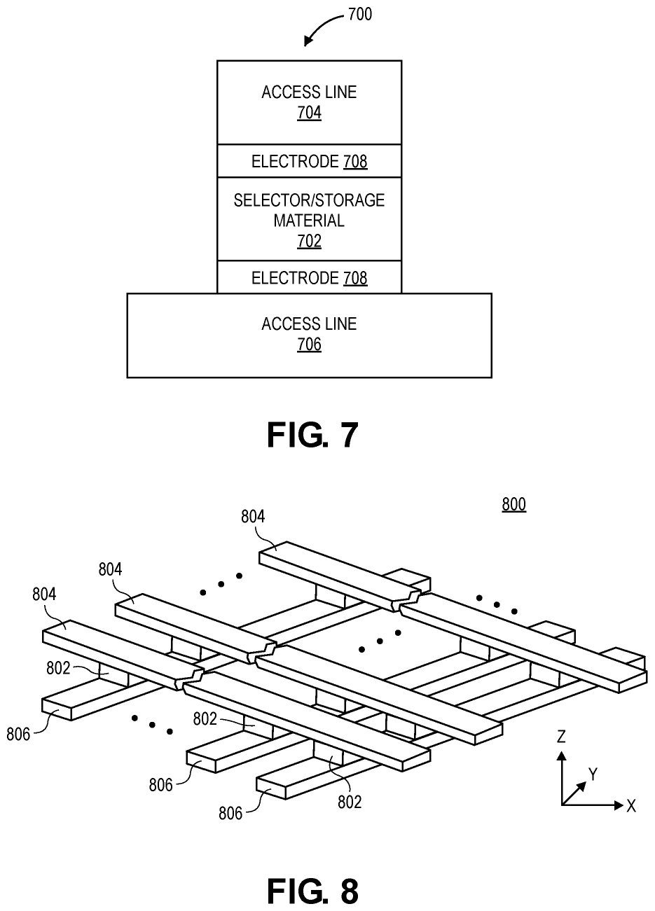

FIG. 8 illustrates a portion of a memory cell array 800, which can include a memory cell such as the memory cell 700 of FIG. 7. The memory cell array 800 is an example of a crosspoint memory array. The memory cell array 800 includes a plurality of access lines 804, 806, which can be the same or similar as the access lines 704, 706 described with respect to FIG. 7. Access lines 804, 806 can be referred to as bit lines and word lines. In the example illustrated in FIG. 8, the bit lines (e.g., access lines 804) are orthogonal to the word lines (e.g., access lines 806). A storage material 802 is disposed between the access lines 804, 806. In one example, a “crosspoint” is formed at an intersection between a bit line and a word line. A memory cell is created from the storage material 802 between the bit line and word line where the bit line and word line intersect. The storage material 802 can be a chalcogenide material, phase change material, both a chalcogenide material and phase change material, or other storage material. In one example, the access lines 804, 806 are composed of one or more conductive materials such as the access lines 704, 706 described above with respect to FIG. 7.

Although a single level or tier of memory cells is shown in FIG. 8 for the sake of clarity, memory cell array 800 typically includes multiple levels, decks, or tiers of non-volatile memory cells (e.g., in the z-direction). Nonvolatile memory devices including multiple tiers of cross-point memory cells may be referred to as three-dimensional (3D), multi-level, or multi-tiered cross-point memory devices. The techniques discussed herein may also apply to other persistent memory types or crosspoint memory architectures (e.g., vertical crosspoint memory in which cells are formed along and around conductive channels). The FIGS. 7 and 8 illustrate examples of a crosspoint memory cell and array that may be accessed with control circuitry including near miss refresh logic. However, the techniques described herein can be implemented for memories having different materials or structures than the examples described in FIGS. 7 and 8.

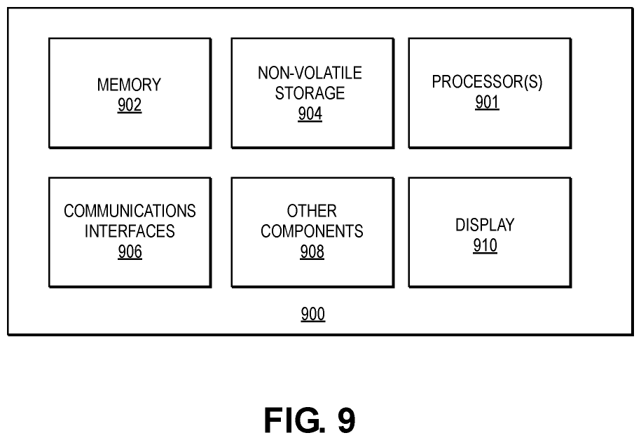

FIG. 9 provides an exemplary depiction of a computing system 900 (e.g., a smartphone, a tablet computer, a laptop computer, a desktop computer, a server computer, etc.). As observed in FIG. 9, the system 900 may include one or more processors or processing units 901. The processor(s) 901 may include one or more central processing units (CPUs), each of which may include, e.g., a plurality of general-purpose processing cores. The processor(s) 901 may also or alternatively include one or more graphics processing units (GPUs) or other processing units. The processor(s) 901 may include and/or be coupled with a memory controller. The processor(s) 901 can be similar to, or the same as, the processor 101 of FIG. 1.

The system 900 also includes memory 902 (e.g., system memory), non-volatile storage 904, communications interfaces 906, a display 910 (e.g., touchscreen, flat-panel), and other components 908. The memory 902 may implement a near miss-based refresh scheme in accordance with examples described herein. The other components may include, for example, a power supply (e.g., a battery or/or other power supply), sensors, power management logic, or other components. The communications interfaces 906 may include logic and/or features to support a communication interface. For these examples, communications interface 906 may include one or more communication or network interfaces that operate according to various communication protocols or standards to communicate over direct or network communication links or channels. Direct communications may occur via use of communication protocols or standards described in one or more industry standards (including progenies and variants) such as those associated with the PCIe specification. Network communications may occur via use of communication protocols or standards such those described in one or more Ethernet standards promulgated by IEEE. For example, one such Ethernet standard may include IEEE 802.3. Network communication may also occur according to one or more OpenFlow specifications such as the OpenFlow Switch Specification. Other examples of communications interfaces include, for example, a local wired point-to-point link (e.g., USB) interface, a wireless local area network (e.g., WiFi) interface, a wireless point-to-point link (e.g., Bluetooth) interface, a Global Positioning System interface, and/or other interfaces.

The computing system also includes non-volatile storage 904, which may be the mass storage component of the system. The non-volatile storage 904 can be similar to, or the same as, the memory device 100 of FIG. 1, described above. Non-volatile storage 904 may include byte or block addressable types of non-volatile memory having a crosspoint memory structure. Non-volatile types of memory may also include other types of byte or block addressable non-volatile memory such as single or multi-level phase change memory (PCM), resistive memory, nanowire memory, ferroelectric transistor random access memory (FeTRAM), magnetoresistive random access memory (MRAM) that incorporates memristor technology, spin transfer torque MRAM (STT-MRAM), or a combination of any of the above. In one example, the non-volatile storage 904 may include mass storage that is composed of one or more SSDs (solid state drives), DIMMs (dual in line memory modules), or other module or drive. The non-volatile storage 904 may implement a near miss-based refresh scheme in accordance with examples described herein.

Examples of read disturb mitigation techniques follow.

### EXAMPLE 1

A memory controller coupled with a crosspoint memory array includes input/output (I/O) circuitry to receive read data from the crosspoint memory array in response to a read request to a target address, and circuitry to: determine a number of error bits in the read data, in response to the read data having a number of error bits that is greater than a threshold: send a refresh write command to the target address to a command queue, in response a determination that there is a write command in the command queue to the target address: drop the refresh write command from the command queue, and convert the write command to a refresh write command.

### EXAMPLE 2

The memory controller of example 1, wherein the circuitry to convert the write command is to: modify an op-code of the write command from a write command op-code to a refresh write command op-code.

### EXAMPLE 3

The memory controller of any of examples 1 and 2, wherein the write command is to write to fewer than all bits in a target codeword, and the refresh write command is to write to all bits in the target codeword.

### EXAMPLE 4

The memory controller of any of examples 1, 2, and 3, wherein the circuitry to determine the number of error bits in the read data is to: decode the read data, the read data including a codeword encoded with an error correction code (ECC).

### EXAMPLE 5

The memory controller of any of examples 1, 2, 3, and 4, wherein the threshold is less than a maximum number of error bits that can be corrected.

### EXAMPLE 6

The memory controller of any of examples 1, 2, 3, 4, and 5, wherein the circuitry is to, in response to the read data having a number of error bits that is greater than a threshold: store the target address and read data in a cache until completion of the refresh write command to the target address.

### EXAMPLE 7

The memory controller of any of examples 1-6, wherein the circuitry is to in response to receipt of a signal indicating completion of the refresh write command to the target address, invalidate an entry in the cache corresponding to the target address.

### EXAMPLE 8

The memory controller of any of examples 1-7, wherein the circuitry is to: in response to receipt of the read request to the target address, check if the target address is in the cache, and in response to a determination that the target address is in the cache, retrieve read data from the cache.

### EXAMPLE 9

The memory controller of any of examples 1-8, wherein the memory controller is on a same module and/or package as the crosspoint memory array.

### EXAMPLE 10

A system including a crosspoint memory array, and a memory controller coupled with the crosspoint memory array. The memory controller includes input/output (I/O) circuitry to: receive a read request to a target address from a host memory controller, send the read request to the crosspoint memory array, and receive read data from the crosspoint memory array in response to the read request, and circuitry to: determine a number of error bits in the read data, in response to the read data having a number of error bits that is greater than a threshold: send a refresh write command to the target address to a command queue, in response a determination that there is a write command in the command queue to the target address: drop the refresh write command from the command queue, and convert the write command to a refresh write command.

### EXAMPLE 11

The system of example 10, wherein the memory controller is in accordance with any of examples 1-9.

### EXAMPLE 12

The system of example 10 or 11, wherein the memory controller is on a same module and/or package as the crosspoint memory array.

### EXAMPLE 13

The system of any of examples 10-12, further including one or more of the host memory controller, a processor coupled with the host memory controller, a display coupled with a processor, a network interface coupled with a processor, and a battery to power the system.

### EXAMPLE 14

A memory controller coupled with a crosspoint memory array, the memory controller including input/output (I/O) circuitry to receive read data from the crosspoint memory array in response to a read request to a target address, and circuitry to: decode the read data and determine a number of error bits in the read data, in response to the read data having a number of error bits that is greater than a threshold: send a refresh write command to the target address to a command queue, and store the target address and read data in a cache until completion of the refresh write command to the target address.

### EXAMPLE 15

The memory controller of example 14, wherein: the circuitry is to: in response to receipt of a signal indicating completion of the refresh write command to the target address, invalidate an entry in the cache corresponding to the target address.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, crosspoint memory, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A memory controller coupled with a crosspoint memory array, the memory controller comprising:
input/output (I/O) circuitry to receive read data from the crosspoint memory array in response to a read request to a target address; and
circuitry to:
determine a number of error bits in the read data,
in response to the read data having a number of error bits that is greater than a threshold:
send a refresh write command to the target address to a command queue,
in response a determination that there is a write command in the command queue to the target address:
drop the refresh write command from the command queue, and
convert the write command to a refresh write command.

2. The memory controller of claim 1, wherein:
the circuitry to convert the write command is to: modify an op-code of the write command from a write command op-code to a refresh write command op-code.

3. The memory controller of claim 1, wherein:
the write command is to write to fewer than all bits in a target codeword, and the refresh write command is to write to all bits in the target codeword.

4. The memory controller of claim 1, wherein:
the circuitry to determine the number of error bits in the read data is to: decode the read data, the read data including a codeword encoded with an error correction code (ECC).

5. The memory controller of claim 1, wherein:
the threshold is less than a maximum number of error bits that can be corrected.

6. The memory controller of claim 1, wherein:
the circuitry is to, in response to the read data having a number of error bits that is greater than a threshold:
store the target address and read data in a cache until completion of the refresh write command to the target address.

7. The memory controller of claim 6, wherein:
the circuitry is to:
in response to receipt of a signal indicating completion of the refresh write command to the target address, invalidate an entry in the cache corresponding to the target address.

8. The memory controller of claim 6, wherein:
the circuitry is to:
in response to receipt of the read request to the target address, check if the target address is in the cache, and
in response to a determination that the target address is in the cache, retrieve read data from the cache.

9. The memory controller of claim 1, wherein:
the memory controller is on a same module and/or package as the crosspoint memory array.

10. A system comprising
a crosspoint memory array; and
a memory controller coupled with the crosspoint memory array, the memory controller comprising:
input/output (I/O) circuitry to:
receive a read request to a target address from a host memory controller,
send the read request to the crosspoint memory array, and
receive read data from the crosspoint memory array in response to the read request; and
circuitry to:
determine a number of error bits in the read data,
in response to the read data having a number of error bits that is greater than a threshold:
send a refresh write command to the target address to a command queue,
in response a determination that there is a write command in the command queue to the target address:
drop the refresh write command from the command queue, and
convert the write command to a refresh write command.

11. The system of claim 10, wherein:
the circuitry to convert the write command is to: modify an op-code of the write command from a write command op-code to a refresh write command op-code.

12. The system of claim 10, wherein:
the write command is to write to fewer than all bits in a target codeword, and the refresh write command is to write to all bits in the target codeword.

13. The system of claim 10, wherein:
the circuitry to determine the number of error bits in the read data is to: decode the read data, the read data including a codeword encoded with an error correction code (ECC).

14. The system of claim 10, wherein:
the threshold is less than a maximum number of error bits that can be corrected.

15. The system of claim 10, wherein:
the circuitry is to, in response to the read data having a number of error bits that is greater than a threshold:
store the target address and read data in a cache until completion of the refresh write command to the target address.

16. The system of claim 15, wherein:
the circuitry is to:
in response to receipt of a signal indicating completion of the refresh write command to the target address, invalidate an entry in the cache corresponding to the target address.

17. The system of claim 10, wherein
the memory controller is on a same module and/or package as the crosspoint memory array.

18. The system of claim 10, further comprising one or more of:
the host memory controller, a processor coupled with the host memory controller, a display coupled with a processor, a network interface coupled with a processor, and a battery to power the system.

19. A memory controller coupled with a crosspoint memory array, the memory controller comprising:
input/output (I/O) circuitry to receive read data from the crosspoint memory array in response to a read request to a target address; and
circuitry to:
decode the read data and determine a number of error bits in the read data,
in response to the read data having a number of error bits that is greater than a threshold:
send a refresh write command to the target address to a command queue, and
store the target address and read data in a cache until completion of the refresh write command to the target address.

20. The memory controller of claim 19, wherein:
the circuitry is to:
in response to receipt of a signal indicating completion of the refresh write command to the target address, invalidate an entry in the cache corresponding to the target address.
